(19) United States
(12) Patent Application Publication
(10) Pub. No.: US 2017/0256596 A1
(43) Pub. Date: Sep. 7, 2017

(54) ORGANIC ELECTROLUMINESCENCE DISPLAY DEVICE

(71) Applicant: Japan Display Inc., Minato-ku (JP)

(72) Inventors: Yuki HAMADA, Minato-ku (JP); Hajime AKIMOTO, Minato-ku (JP)

(73) Assignee: Japan Display Inc., Minato-ku (JP)

(21) Appl. No.: 15/446,425

(22) Filed: Mar. 1, 2017

(30) Foreign Application Priority Data
Mar. 1, 2016 (JP) 2016-039426

(51) Int. Cl. H01L 27/32; H01L 51/52

(52) U.S. Cl. CPC H01L 27/3246; H01L 51/5209; H01L 51/5253

(57) ABSTRACT

An organic electroluminescence display device has a barrier structure that is placed on an upper electrode. The barrier structure has a first organic sealing layer disposed between a first inorganic sealing layer and a second inorganic sealing layer. The first organic sealing layer is divided by the second inorganic sealing layer with respect to each of a plurality of partial areas that form a display area in a plan view and is thicker than a bank having a shape that rises upward.

### CROSS-REFERENCE TO RELATED APPLICATION

The present application claims priority from Japanese application JP2016-039426 filed on Mar. 1, 2016, the content of which is hereby incorporated by reference into this application.

### BACKGROUND OF THE INVENTION

1. Field of the Invention

The present invention relates to an organic electroluminescence display device.

2. Description of the Related Art

In an organic electroluminescence display device, each pixel is provided with a lower electrode, and a bank that separates the pixels from one another is formed on outer peripheral portions of the lower electrodes. Organic layers including a light emitting layer, a charge transport layer, and other layers are formed above the bank and the lower electrodes, and an upper electrode is formed above the organic layers (organic layers including light emitting layer, charge transport layer, and other layers are hereinafter referred to as light emitting organic layer). In many organic electroluminescence display devices, a sealing layer covers the upper electrode to prevent moisture from penetrating the light emitting organic layer. In JP 2013-134989 A, JP 2014-154450 A, and JP 2014-179278 A, a sealing layer made of an organic material is formed between two sealing layers made of an inorganic material (a sealing layer made of an inorganic material is hereinafter referred to as an inorganic sealing layers, and a sealing layer made of an organic material is hereinafter referred to as an organic sealing layer). According to the sealing layers described above, even in a case where a hole is produced in the upper inorganic sealing layer due, for example, to foreign matter trapped in the step of manufacturing the organic electroluminescence display device, the lower inorganic sealing layer can prevent moisture having intruded through the hole from penetrating the light emitting organic layer.

### SUMMARY OF THE INVENTION

In a structure in which an organic sealing layer formed between two inorganic sealing layers is continuously formed over an entire display area, when moisture penetrates the organic sealing layer through a hole produced in the upper inorganic sealing layer, the moisture possibly spreads widely in the organic sealing layer. Therefore, in a case where a hole resulting from foreign matter is produced in the upper inorganic sealing layer and a hole resulting from foreign matter is also produced in the lower inorganic sealing layer, and even if the positions of the two holes are separate from each other by a large distance, the moisture having intruded through the hole in the upper inorganic sealing layer spreads widely in the organic sealing layer and possibly reaches the hole in the lower inorganic sealing layer. In this regard, in the organic electroluminescence display device described in JP 2013-134989 A, the organic sealing layer is divided into partial areas on a pixel basis. In the organic electroluminescence display devices described in JP 2014-154450 A and JP 2014-179278 A, the organic sealing layer is divided into smaller partial areas. A situation in which the moisture spreads widely in the organic sealing layer is therefore avoided.

In JP 2013-134989 A, however, the organic sealing layer is so formed as to be thinner than the bank so that the organic sealing layer is not higher than the bank or the light emitting organic layer or the upper electrode formed above the bank. Further, since the lower inorganic sealing layer is extremely thin, the lower inorganic sealing layer is also divided by the step between the light emitting organic layer and the upper electrode. The structure described above is therefore unlikely to provide sufficient sealing performance. For example, in a case where foreign matter having a size greater than the thickness of the bank is trapped in the organic sealing layer or the lower inorganic sealing layer, the upper inorganic sealing layer is possibly divided due to the foreign matter. Further, also in the structures described in JP 2014-154450 A and JP 2014-179278 A, since the organic sealing layer is thinner than the bank, sufficient sealing performance is unlikely to be provided.

An object of the invention is to provide an organic electroluminescence display device capable of preventing moisture from widely spreading via an organic sealing layer to improve sealing performance.

An organic electroluminescence display device according to an aspect of the invention includes a display area where a plurality of pixels are arranged, a plurality of lower electrodes arranged in each of the plurality of pixels, a bank that is provided between adjacent two of the pixels, covers a periphery of each of the lower electrodes, and has a shape that rises upward, a light emitting organic layer that is continuously placed on the plurality of lower electrodes and the bank, the light emitting organic layer having first raised sections that rise in corresponding with the shape of the bank, an upper electrode that is continuously placed on the light emitting organic layer and is placed above the plurality of lower electrodes and the bank, the upper electrode having second raised sections that rise in correspondence with the first raised sections of the light emitting organic layer, and a barrier structure that is placed on the upper electrode. The barrier structure has a first inorganic sealing layer, a second inorganic sealing layer covering the first inorganic sealing layer, and a first organic sealing layer disposed between the first inorganic sealing layer and the second inorganic sealing layer and divided by the second inorganic sealing layer for each of a plurality of partial areas that form the display area in a plan view, and the first organic sealing layer is thicker than the bank. The configuration described above can prevent moisture from widely spreading via the organic sealing layer, whereby the sealing performance can be improved.

An organic electroluminescence display device according to another aspect of the invention includes a display area where a plurality of pixels are arranged, a plurality of lower electrodes each arranged in each of the plurality of pixels, a bank that is provided between adjacent two of the pixels, covers a periphery of each of the lower electrodes, and has a shape that rises upward, a light emitting organic layer that is continuously placed on the plurality of lower electrodes and the bank, the light emitting organic layer having first raised sections that rise in corresponding with the shape of the bank, an upper electrode that is continuously placed on the light emitting organic layer and is placed above the plurality of lower electrodes and the bank, the upper electrode having second raised sections that rise in correspondence with the first raised sections of the light emitting organic layer, and a barrier structure that is placed on the upper electrode. The barrier structure has a first inorganic sealing layer, a second inorganic sealing layer covering the first inorganic sealing layer, and a first organic sealing layer disposed between the first inorganic sealing layer and the second inorganic sealing layer and divided by the second inorganic sealing layer with respect to each of a plurality of partial areas that form the display area in a plan view, and the first inorganic sealing layer is thicker than the lower electrodes, the light emitting organic layer, and the upper electrode. The configuration described above can prevent moisture from widely spreading via the organic sealing layer, whereby the sealing performance can be improved.

### BRIEF DESCRIPTION OF THE DRAWINGS

FIG. 1 schematically shows the upper surface of an organic electroluminescence display device according to an embodiment of the invention.

FIG. 2 is an enlarged view of the upper surface within the line II-II in FIG. 1.

FIG. 3 is a cross-sectional view taken along the line in FIG. 2.

FIG. 4 schematically shows a circuit section incorporated in the organic electroluminescence display device.

FIG. 5 shows an upper surface that is an enlarged portion of a display area in an organic electroluminescence display device according to a first variation.

FIG. 6 is a cross-sectional view taken along the line VI-VI in FIG. 5.

FIG. 7A shows another variation of the organic electroluminescence display device according to the first variation and shows an upper surface that is an enlarged portion of the display area.

FIG. 7B shows another variation of the organic electroluminescence display device according to the first variation and shows an upper surface that is an enlarged portion of the display area.

FIG. 7C shows another variation of the organic electroluminescence display device according to the first variation and shows an upper surface that is an enlarged portion of the display area.

FIG. 8 is a cross-sectional view of an organic electroluminescence display device according to a second variation.

FIG. 9 is a cross-sectional view of an organic electroluminescence display device according to a third variation.

FIG. 10 is a cross-sectional view of an organic electroluminescence display device according to a fourth variation.

FIG. 11 is a cross-sectional view of an organic electroluminescence display device according to a fifth variation.

### DETAILED DESCRIPTION OF THE INVENTION

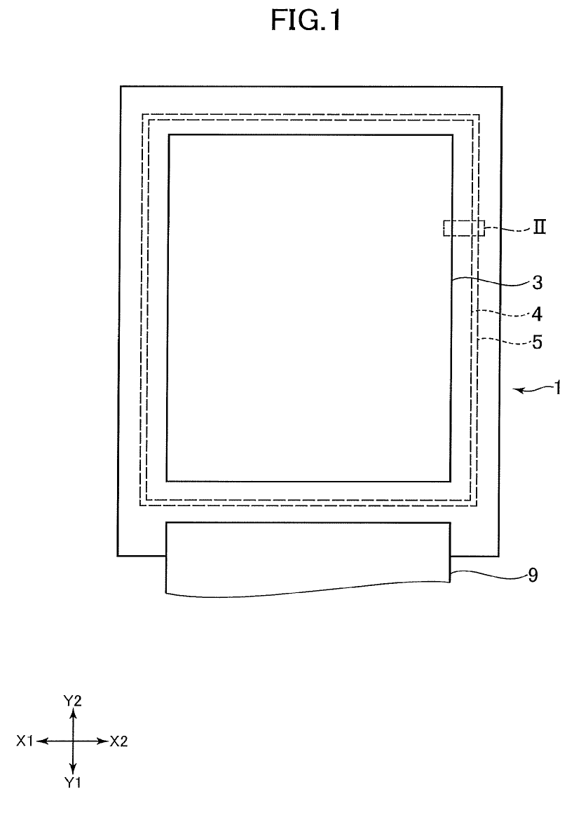

A form (embodiment) for implementing the invention will be described below with reference to FIGS. 1 to 4. The disclosure in the present specification is merely an example of the invention, and appropriate changes which keep the substance of the invention and which a person skilled in the art can readily conceive of fall within the scope of the invention. The width, thickness, shape, and other factors of each portion shown in the drawings are diagrammatically drawn and are not intended to limit the interpretation of the invention.

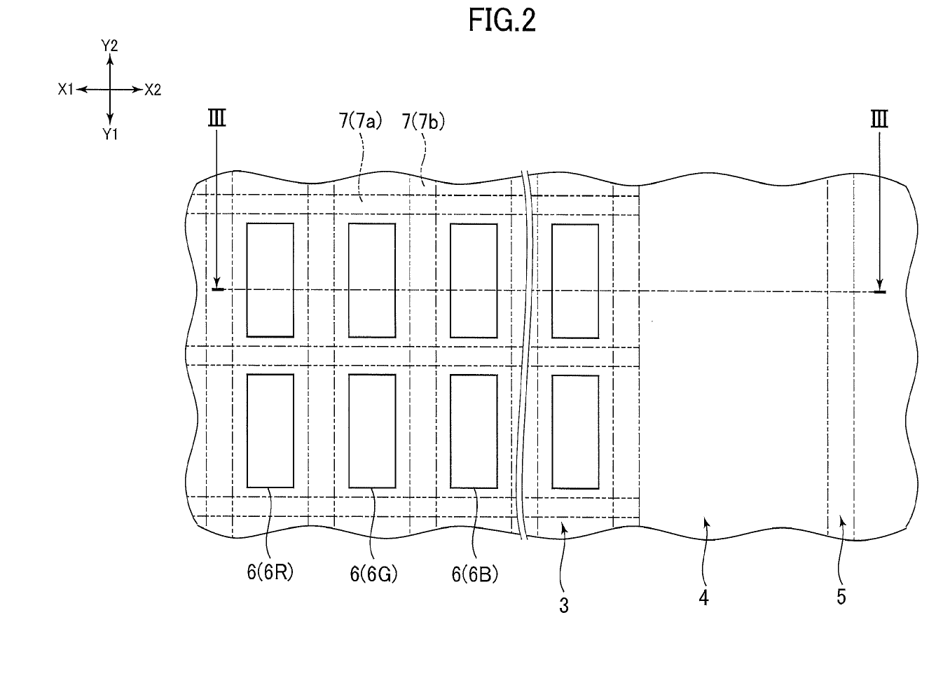

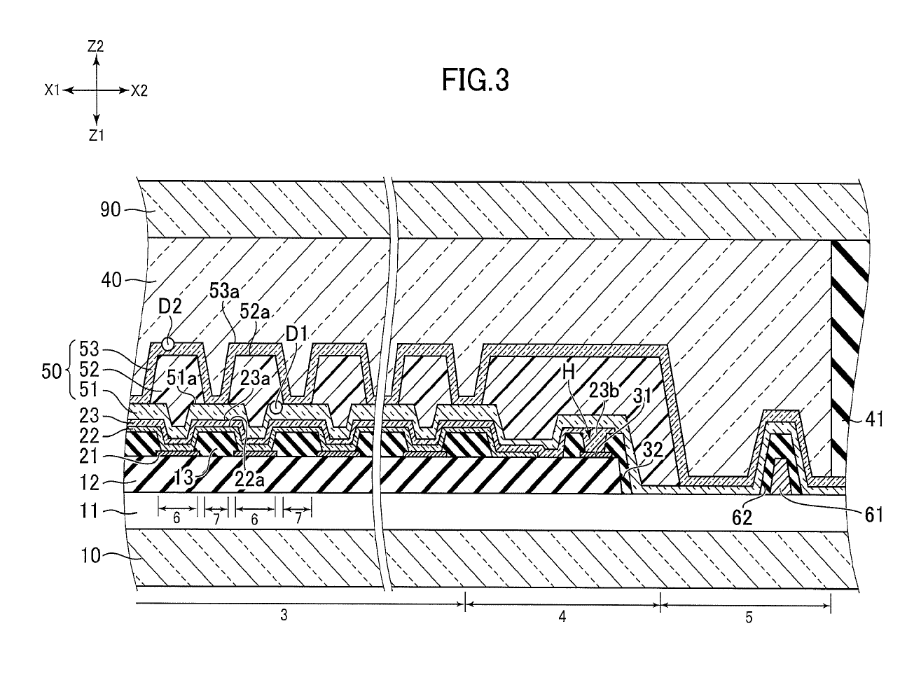

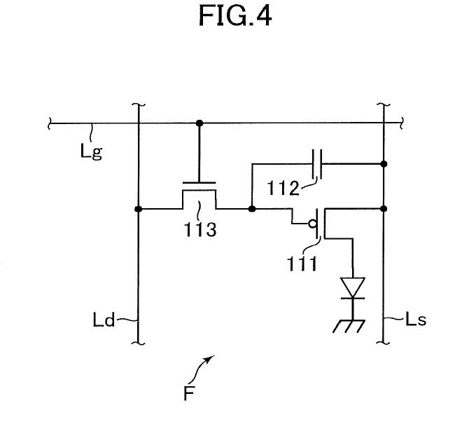

FIG. 1 schematically shows the upper surface of an organic electroluminescence display device 1 according to the present embodiment. FIG. 2 is an enlarged view of the upper surface within the line II-II in FIG. 1. FIG. 3 is a cross-sectional view taken along the line in FIG. 2. FIG. 4 schematically shows a circuit section F incorporated in the organic electroluminescence display device 1. In the following description, the positional relationship among components will be described by using coordinates on an X axis (directions X1 and X2), a Y axis (directions Y1 and Y2) , and a Z axis (directions Z1 and Z2).

### [1. Configuration of Organic Electroluminescence Display Device According to Embodiment]

The organic electroluminescence display device 1 has a display area 3, which is an image displaying area that has a roughly rectangular shape in a plan view, as shown in FIG. 1. A flexible printed circuit (FPC) board 9 for transmitting a predetermined voltage, control signal, image signal, and other pieces of information is attached to the organic electroluminescence display device 1. The organic electro luminescence display device 1 receives an image signal via the flexible printed circuit board 9 to display an image in the display area 3.

The organic electroluminescence display device 1 further has a circumferential edge area 4, which surrounds the circumferential edge of the display area 3, and a moisture blocking area 5, which surrounds the outer side of the circumferential edge area 4, as shown in FIG. 1. The circumferential edge area 4 and the moisture blocking area 5 will be described later in detail.

The display area 3 is provided with a plurality of pixel areas 6, which are secondary pixels that form a display image (hereinafter also simply referred to as pixels), as shown in FIG. 2. More specifically, the display area 3 is provided with, as the pixel areas 6, red pixel areas 6R, which output red light, green pixel areas 6G, which output green light, and blue pixel areas 6B, which output blue light. Although not shown, white pixel areas that output white light may be formed as the pixel areas 6. In the example shown in FIG. 2, the plurality of pixel areas 6 are arranged along the X-axis direction and the Y-axis direction. Division lines 7 are formed between the pixel areas 6. The Division lines 7 are areas where a first organic sealing layer 52 is divided. More specifically, lateral division lines 7a, which linearly extend along the rightward/leftward direction (X-axis direction), and longitudinal division lines 7b, which linearly extend along the frontward/rearward direction (Y-axis direction), are formed. The arrangement and positions of the plurality of pixel areas 6 are not limited to those described above. For example, the pixel areas 6 may be arranged in a zigzag pattern in which the pixel areas 6 adjacent to each other in the X-axis direction are shifted with respect to each other in the Y-axis direction. The division lines 7 only need to be formed in the area that does not overlap with the pixel areas 6.

The organic electroluminescence display device 1 has a structure in which a lower substrate 10 and an upper substrate 90 are bonded to each other, as shown in FIG. 3. The space between the lower substrate 10 and the upper substrate 90 is filled with a filler layer 40. The filler layer 40 may be formed, for example, by causing a transparent filler material to flow into a space surrounded by a sealer 41, which functions as a stopper. The lower substrate 10 and the upper substrate 90 form the front surface and the rear surface of the organic electroluminescence display device 1 and cover the display area 3, the circumferential edge area 4, and the moisture blocking area 5 in a plan view. The lower substrate 10 and the upper substrate 90 may be made, for example, of a hard insulating material, such as a resin and a glass material, or maybe made of an insulating material having flexibility, such as a polyimide.

A variety of layers for achieving image display in the display area 3 are formed above the lower substrate 10 (on the Z2-direction side thereof). More specifically, on the lower substrate 10 are layered a circuit layer 11, a planarizing layer 12, a bank 13, lower electrodes 21, alight emitting organic layer 22, and an upper electrode 23. A barrier structure 50 is continuously placed on the upper side of the upper electrode 23. The barrier structure 50 is formed above the lower substrate 10.

The circuit layer 11 is layered on the upper side of the lower substrate 10. A plurality of circuit sections F (see FIG. 4), each of which contains TFTs (thin film transistors) and capacitance, are formed in the circuit layer 11. The circuit sections F are arranged in the positions corresponding to the plurality of pixel areas 6 in a plan view.

The circuit section F shown in FIG. 4 controls image display in the display area 3 by controlling supply of current to the lower electrodes 21. Each of the circuit sections F incorporated in the circuit layer 11 has, as wiring lines, a scan line Lg, which extends in the horizontal direction, a video signal line Ld, which extends in the vertical direction, and a power line Ls, which extends in the vertical direction. The circuit section F further has a drive TFT 111, retention capacitance 112, and a switching TFT 113. The gate of the switching TFT 113 is connected to the scan line Lg, and the drain of the switching TFT 113 is connected to the video signal line Ld. The source of the switching TFT 113 is connected to the retention capacitance 112 and the gate of the drive TFT 111. The source of the drive TFT 111 is connected to the power line Ls, and the corresponding lower electrode 21 is connected to the drain of the drive TFT 111. Applying gate voltage to the scan line Lg turns on the switching TFT 113. At this point, when a video signal is supplied via the video signal line Ld, charge is accumulated in the retention capacitance 112. The accumulation of the charge in the retention capacitance 112 turns on the drive TFT 111. Current therefore flows through the power line Ls to the lower electrode 21, the light emitting organic layer 22, and the upper electrode 23, and the light emitting organic layer 22 outputs light.

The planarizing layer 12 is made of an organic insulating material, such as a resin. The planarizing layer 12 is layered on the upper side of the circuit layer 11, as shown in FIG. 3. Contact holes that are not shown are formed in the planarizing layer 12, and the lower electrodes 21 are connected through the holes to the circuit sections F. In the present embodiment, the planarizing layer 12 extends to the circumferential edge area 4, and the circuit layer 11 extends to the circumferential edge area 4 and the moisture blocking area 5 outside the circumferential edge area 4.

A plurality of lower electrodes 21 are made of a predetermined conductive material. The plurality of lower electrodes 21 are arranged on the upper side of the planarizing layer 12. The plurality of lower electrodes 12 are arranged in each of the plurality of pixel areas 6 in a plan view. That is, each of the lower electrodes 21 is located inside the right and left positions (position in X-axis direction) and the front and rear position (position in Y-axis direction) of the corresponding pixel area 6. The lower electrodes 21 maybe formed, for example, by forming a conductive material layer having a roughly uniform thickness on the upper side of the planarizing layer 12 and processing (etching, for example) the layer in such a way that the layer is divided along the boundaries between the pixel areas 6.

A conductive section 31 is made of a predetermined conductive material. The conductive section 31 is formed on the upper side of the planarizing layer 12 in the circumferential edge area 4. The conductive section 31 is formed in the layer where the lower electrodes 21 are formed, as shown in FIG. 3. The conductive section 31 may be made of the conductive material of which the lower electrodes 21 are made.

The bank 13 is made of an organic insulating material, such as a resin. The bank 13 is disposed between the plurality of lower electrodes 21. The bank 13 is so disposed as to surround the outer circumference of each of the plurality of pixel areas 6 and so disposed as to cover the periphery of each of the lower electrodes 21 (more specifically, entire circumference of each of lower electrodes 21). The thus disposed bank 13 prevents the light emitting organic layer 22 from being divided at the edges of lower electrodes 21 adjacent to each other in correspondence with pixel areas 6 and therefore prevents a short circuit between the lower electrodes 21 and the upper electrode 23. In the present embodiment, the bank 13 is located between the plurality of lower electrodes 21. The bank 13 is placed on end portions of the lower electrodes 21 and has a shape that rises above the lower electrodes 21 (in direction Z2). More specifically, the bank 13 is so formed as to be thicker than the lower electrodes 21. For example, the thickness of the lower electrodes 21 may be set a value ranging from 0.15 to 0.20 μm, and the thickness of the bank 13 may be set at a value ranging from 1.00 to 2.00 μm.

An edge section 32 is made of an organic insulating material, such as a resin. The edge section 32 is formed on the upper side of the planarizing layer 12 in the circumferential edge area 4. The edge section 32 is so provided as to be placed on end portions of the conductive section 31. A contact hole H is formed in the edge section 32. The contact hole H which exposes a central portion of the conductive section 31. The edge section 32 may be made of the insulating material of which the bank 13 is made.

The light emitting organic layer 22 is formed on the upper side of the lower electrodes 21 and the bank 13. The light emitting organic layer 22 is so provided as to be continuously placed on the lower electrodes 21 and the bank 13 in a plan view, and the light emitting organic layer 22 is disposed over all the pixel areas 6 in the display area 3. The light emitting organic layer 22 shown in FIG. 3 extends beyond the display area 3 and reaches the circumferential edge area 4 but does not reach the conductive section 31 disposed in the circumferential edge area 4.

The light emitting organic layer 22 outputs light of a plurality of pixels that form a display image. The light emitting organic layer 22 is formed of a laminate of a hole injecting layer, a hole transporting layer, a light emitting layer, an electron transporting layer, and an electron injecting layer that are not shown. The light of the pixels that form a display image is outputted from a portion which forms the light emitting organic layer 22 and through which electricity conducts. More specifically, when current flows through the lower electrodes 21, the light emitting organic layer 22, and the upper electrode 23, light is outputted from portions of the light emitting organic layer 22 that correspond to the pixel areas 6. In a case where the organic electroluminescence display device 1 outputs light from the pixels toward the upper substrate 90 (in a case where what is called a top emission method is employed), each of the layers disposed above the light emitting organic layer 22 is so formed as to be transparent or translucent. In this case, the lower electrodes 21 may contain a material that reflects light, such as a metal (Ag, for example).

Further, the light emitting organic layer 22 (more specifically, light emitting layer that is not shown but is contained in light emitting organic layer 22) is colored in predetermined colors (three colors including red, green, and blue or four colors including white in addition to the three colors, for example) for each of the plurality of pixel areas 6. The light emitting organic layer 22 thus colored in different colors allows the light outputted from each of the plurality of pixel areas 6 to be colored. Instead of using the light emitting organic layer 22 colored in different colors, a color filter layer that is not shown may be formed above the light emitting organic layer 22 (below upper substrate 90, for example). In this case, the color filter layer may be provided with color filters that transmit color light fluxes having predetermined colors corresponding to the plurality of pixel areas 6.

The upper electrode 23 is formed on the upper side of the light emitting organic layer 22. The upper electrode 23 is disposed above the plurality of lower electrodes 21 and the bank 13 and so provided as to be continuously placed on the light emitting organic layer 22. The upper electrode 23 is disposed over the display area 3 and the circumferential edge area 4. The upper electrode 23 may be made of a transparent conductive material, such as ITO (indium tin oxide) or IZO (indium zinc oxide).

In the circumferential edge area 4, the upper electrode 23 extends beyond the end of the light emitting organic layer 22 to the position of the conductive section 31. A contact section 23b is formed at the position on the upper electrode 23 that corresponds to the conductive section 31. The contact section 23b is a portion in contact with the conductive section 31. The contact section 23b fills the contact hole H formed in the edge section 32, which is located in the layer where the bank 13 is located, so that the contact section 23b is in contact with the conductive section 31. In the example shown in FIG. 3, the contact section 23b is so formed as to be thicker than the upper electrode 23 in the display area 3 so that the contact hole H is filled with the contact section 23b. The configuration described above in which the upper electrode 23 is electrically connected to the conductive section 31 via the contact section 23b allows reduction in the overall electric resistance of the upper electrode 23 and therefore guarantee of the amount of current flowing through the light emitting organic layer 22. Decrease in luminance in the display area 3 can thus be avoided.

A first insulating layer 61 and a second insulating layer 62, each of which is made of an organic insulating material, such as a resin, are formed in the moisture blocking area 5, as shown in FIG. 3. The first insulating layer 61 is formed in the layer where the planarizing layer 12 is formed, but the first insulating layer 61 is separated from the planarizing layer 12 by a predetermined distance. The second insulating layer 62 is located in the layer where the bank 13 and the edge section 32 are located and covers the upper side of the first insulating layer 61. The second insulating layer 62 is also separated from the edge section 32 by a predetermined distance. A first inorganic sealing layer 51 is then so provided as to cover the thus divided portion of the organic insulating layers.

Externally intruding moisture travels through a layer made of an organic material, such as a resin. Providing the moisture blocking area 5, where the organic insulating materials are divided, can therefore prevent the moisture from intruding into the light emitting organic layer 22 or the variety of electrodes provided in the display area 3 and the circumferential edge area 4.

As described above, the bank 13 has a shape that rises upward (in direction Z2) beyond the lower electrodes 21 between every pair of two lower electrodes 21. The light emitting organic layer 22 has a roughly uniform thickness in the display area 3. The light emitting organic layer 22 has first raised sections 22a that has a shape rising upward in correspondence with the shape of the bank 13. The upper electrode 23 similarly has a roughly uniform thickness in the display area 3. The upper electrode 23 has second raised sections 23a that has a shape rising upward in correspondence with the shape of the first raised sections 22a of the light emitting organic layer 22. The first and second raised sections 22a, 23a are formed in the positions of the bank 13 in a plan view.

Further, in the present embodiment, the light emitting organic layer 22 is so formed as to be roughly as thick as the lower electrodes 21, and the upper electrode 23 in the display area 3 is so formed as to be thinner than the lower electrodes 21. For example, with respect to the lower electrodes 21 so formed as to have the thickness ranging from 0.15 to 0.20 μm, the light emitting organic layer 22 may have a thickness ranging from 0.15 to 0.30 μm, and the upper electrode 23 may have a thickness ranging from 0.01 to 0.02 μm.

The barrier structure 50 for preventing air and moisture from intruding into the light emitting organic layer 22 or the variety of electrodes is formed on the upper side of the upper electrode 23. The barrier structure 50 is intended to prevent oxygen and moisture from intruding into the upper electrode 23 or the light emitting organic layer 22 and is continuously placed on the upper electrode 23. In the present embodiment, the barrier structure 50 has a first inorganic sealing layer 51 covering the upper electrode 23, a second inorganic sealing layer 53 covering the first inorganic sealing layer 51, and a first organic sealing layer 52 locating between the first inorganic sealing layer 51 and the second inorganic sealing layer 53. Each of the first and second inorganic sealing layers 51, 53 is made of an inorganic insulating material, such as SiOx or SiNy, and the first organic sealing layer 52 is made of an organic insulating material, such as a resin. The first and second inorganic sealing layers 51, 53 are intended to prevent moisture intrusion, and the first organic sealing layer 52 is intended to cover foreign matter Dl, such as dust and dirt, trapped after the upper electrode 53 is formed.

The first inorganic sealing layer 51 continuously extends over the display area 3, the circumferential edge area 4, and the moisture blocking area 5 and covers the lower substrate 10. In the display area 3 and the circumferential edge area 4, the first inorganic sealing layer 51 covers the upper side of the upper electrode 23 and also covers the planarizing layer 12, which is made of an organic insulating material, and the edge section 32, which is formed in the layer where the bank 13 is formed, in the circumferential edge area 4. In the moisture blocking area 5, the first inorganic sealing layer 51 is so formed as to extend and climb over the first and second insulating layers 61, 62 and as to be continuously placed on the circuit layer 11 in the portion where the organic insulating layers are divided. The configuration described above in which the inorganic sealing layer 51 covers the upper electrode 32, the planarizing layer 12, and the edge section 32 can prevent moisture from intruding into the layers made of organic materials.

Further, the first inorganic sealing layer 51 is so formed as to have a roughly uniform thickness, as the upper electrode 23 in the display area 3, and has third raised sections 51a, which are portions that rise upward in correspondence with the shape of the second raised sections 23a of the upper electrode 23. The first inorganic sealing layer 51 is so formed as to be thicker than the lower electrodes 21, the light emitting organic layer 22, and the upper electrode 23. For example, with respect to the lower electrodes 21, the light emitting organic layer 22, and the upper electrode 23, each of which is so formed to have a thickness ranging from 0.01 to 0.30 μm, the thickness of the first inorganic sealing layer 51 may be set at a value ranging from 0.50 to 1.00 μm. When the first inorganic sealing layer 51 is so formed as to be thicker than the light emitting organic layer 22 as described above, the first inorganic sealing layer 1 can seamlessly cover the upper side of the upper electrode 23, for example, even in a case where the light emitting organic layer 22 has a step that is large to some extent, whereby the performance of sealing the light emitting organic layer 22 can be improved.

The second inorganic sealing layer 53 is so disposed as to cover the first inorganic sealing layer 51 and continuously extends over the display area 3, the circumferential edge area 4, and the moisture blocking area 5. The second inorganic sealing layer 53 divides the first organic sealing layer 52 at each predetermined area. At the division lines 7, where the first organic sealing layer 52 is divided, the second inorganic sealing layer 53 is in contact with the first inorganic sealing layer 51. The second inorganic sealing layer 53 has, in correspondence with the shape of the first organic sealing layer 52 provided in each of the plurality of pixel electrodes 6, a shape that rises upward in the pixel area 6. The second inorganic sealing layer 53 may be as thick as the first inorganic sealing layer 51 or may be thicker than the first inorganic sealing layer 51. For example, with respect to the first inorganic sealing layer 51 so formed as to have the thickness ranging from 0.50 to 1.00 μm, the thickness of the second inorganic sealing layer 53 may be set at a value ranging from 1.00 to 2.00 μm. Increasing the thickness of the second inorganic sealing layer 53 can prevent the second inorganic sealing layer 53 from being divided or broken, whereby the performance of sealing the light emitting organic layer 22 can be improved.

The first organic sealing layer 52 is disposed between the first inorganic sealing layer 51 and the second inorganic sealing layer 53 in the upward/downward direction (Z-axis direction). For example, when the foreign matter D1 is trapped after the upper electrode 23 is formed, the first inorganic sealing layer 51 is divided or becomes thinner than the other portions at the location where the foreign matter D1 adheres, and the sealing performance of the first inorganic sealing layer 51 therefore lowers. Even in this case, since the first organic sealing layer 52 covers the foreign matter Dl, and the second inorganic sealing layer 53 is formed above the first organic sealing layer 52, the performance of sealing the light emitting organic layer 22 can be improved.

Further, the first organic sealing layer 52 is divided by the second inorganic sealing layer 53 at each predetermined area that forms the display area 3 in a plan view. The first organic sealing layer 52 is divided at the division lines 7. More specifically, the first organic sealing layer 52 is divided at the positions where the bank 13 is disposed. In the present embodiment, the first organic sealing layer 52 is divided for each of the pixel areas 6, as shown in FIG. 3. The first organic sealing layer 52 may be formed, for example, by covering the upper side of the first inorganic sealing layer 51 with an organic insulating material and then irradiating the organic insulating material with light, such as a laser beam, to divide the organic insulating material into a plurality of areas. Dividing the first organic sealing layer 52 into a plurality of areas as described above prevents moisture from widely spreading via the first organic sealing layer 52.

For example, when foreign matter D2 is trapped in the second inorganic sealing layer 53, a hole is formed around the foreign matter D2 in some cases. When moisture intrudes through the hole, the moisture spreads in the first organic sealing layer 52 and reaches the first inorganic sealing layer 51 below the first organic sealing layer 52. If the first organic sealing layer 52 is not divided into a plurality of areas, the moisture having intruded through the hole in the second inorganic sealing layer 53 travels in the first organic sealing layer 52 in the rightward leftward direction (X-axis direction in FIG. 3, for example) and undesirably spreads over the entire display area 3. In this case, the moisture is also transported to the foreign matter D1 trapped in a position different from the position of the foreign matter D2 and undesirably intrudes into the upper electrode 23 and the light emitting organic layer 22 through the hole formed around the foreign matter D1 in the first inorganic sealing layer 51. The light emitting organic layer 22 is degraded due to the moisture having thus intruded therein to, resulting in a problem, such as creation of an area incapable of outputting light (light emission defective area) in the display area 3.

To avoid the problem described above, the first organic sealing layer 52 formed between the foreign matter D1 and foreign matter D2 is divided by the second inorganic sealing layer 53 to prevent the moisture from widely spreading in the first organic sealing layer 52. The moisture having intruded along the circumference of the foreign matter D2 is blocked by the second inorganic sealing layer 53 and cannot therefore reach the foreign matter Dl or therearound. That is, intrusion of the moisture to the upper electrode 23 or the light emitting organic layer 22 can be avoided. In a case where the position of the foreign matter D1 trapped in the first inorganic sealing layer 51 roughly coincides with the position of the foreign matter D2 trapped in the second inorganic sealing layer 53 in a plan view (in a case where foreign matter Dl and foreign matter D2 is trapped in the same pixel area 6), the moisture having intruded via the foreign matter D2 undesirably reaches the foreign matter D1, but the probability of intrusion of the foreign matter D1 and the foreign matter D2 into roughly the same portion is extremely low. Dividing the first organic sealing layer 52 therefore allows the probability of intrusion of moisture into the upper electrode 23 and the light emitting organic layer 22 to be greatly lowered.

Further, the first organic sealing layer 52 is so formed as to be thicker than the bank 13. As a result, an upper surface 52a of the first organic sealing layer 52 is located above the second and third raised sections 23a, 51a, which are raised in correspondence with the shape of the bank 13.

For example, with respect to the bank 13 so formed as to have the thickness ranging from 1.00 to 2.00 μm, the thickness of the first organic sealing layer 52 may be set at a value ranging from 40.00 to 50.00 μm.

The configuration described above in which the thick first organic sealing layer 52 is formed allows the first organic sealing layer 52 to cover the foreign matter Dl, for example, even in a case where foreign matter D1 having a size greater than the thickness of the bank 13 is trapped in the first inorganic sealing layer 51, whereby a situation in which the foreign matter D1 divides the second inorganic sealing layer 53 can be avoided. Further, since the first organic sealing layer 52 can sufficiently cover the foreign matter D1, the upper surface 52a of each of the divided first organic sealing layers 52 can be planarized, and an upper surface 53a of the second inorganic sealing layer 53, which is placed on the upper surfaces 52a, can also be planarized with no inclination in the upward/downward direction (Z-axis direction). Since the second inorganic sealing layer 53 is formed with no inclination, the thickness of the second inorganic sealing layer 53 is made uniform, whereby external intrusion of moisture and oxygen can be avoided.

The first organic sealing layer 52 is also formed in the circumferential edge area 4. The first organic sealing layer 52 in the circumferential edge area 4 covers the contact hole H and the layers formed therearound. The first organic sealing layer 52 in the circumferential edge area 4 may not necessarily be divided.

Further, the first organic sealing layer 52 is isolated from the filler layer 40 by the first inorganic sealing layer 51 and the second inorganic sealing layer 53 in the area outside the display area 3. That is, no first organic sealing layer 52 is formed in the moisture blocking area 5, and the first inorganic sealing layer 51 and the second inorganic sealing layer 53 are in contact with each other. Providing a portion where no layer made of an organic material is formed as described above can prevent moisture from externally passing through an organic layer and intruding into the light emitting organic layer 22 or the variety of electrodes.

As described above, in the present embodiment, since the first organic sealing layer 52 in the barrier structure 50 is divided at each predetermined area (for each of pixel areas 6, for example), a situation in which moisture widely spreads in the first organic sealing layer 52 is avoided. Further, since the first organic sealing layer 52 is so formed as to be thicker than the bank 13, the foreign matter D1 trapped in the first inorganic sealing layer 51 can be reliably covered, whereby formation of a hole in the second inorganic sealing layer 53 resulting from the foreign matter D1 can be avoided. Moreover, since the first inorganic sealing layer 51 is also so formed as to be thicker than the lower electrodes 21, the light emitting organic layer 22, and the upper electrode 23, the first inorganic sealing layer 51 can seamlessly cover the upper side of the upper electrode 23 even in a case where the light emitting organic layer 22 has a step that is large to some extent, whereby the performance of sealing the light emitting organic layer 22 can be improved.

### [2. Variations]

The invention is not limited to the embodiment described above, and a variety of changes may be made thereto. Other exemplary forms (variations) for implementing the invention will be described below.

### [2-1. First Variation]

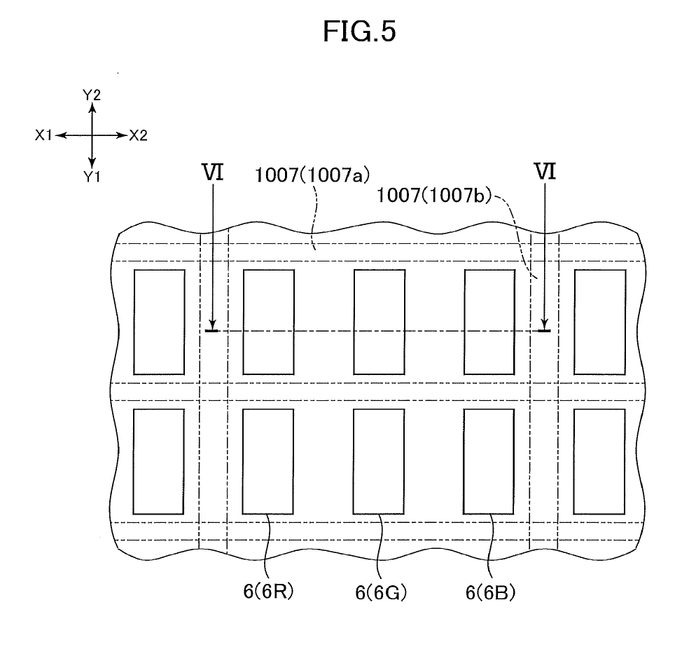

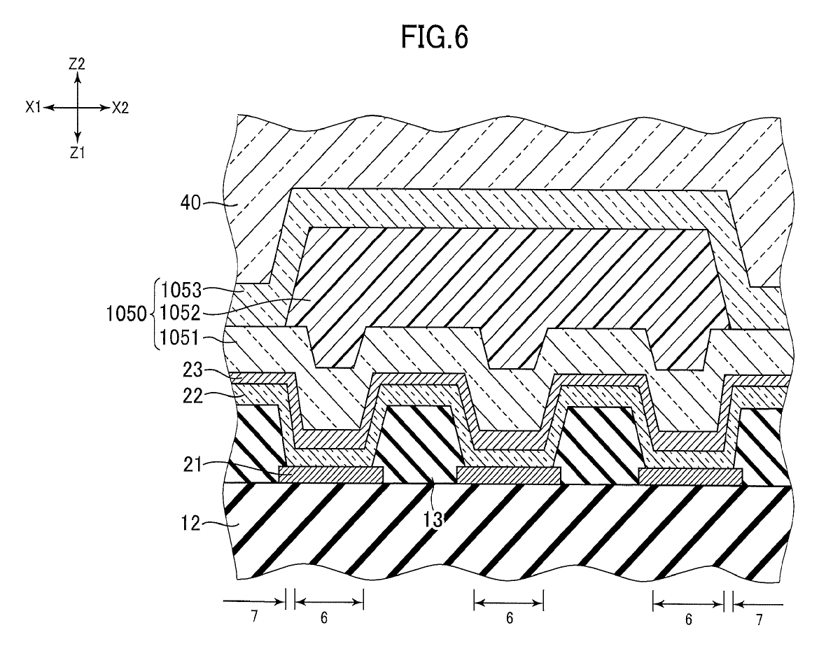

A first variation will be described below with reference to FIGS. 5 and 6. FIG. 5 shows an upper surface that is an enlarged portion of the display area 3 in an organic electroluminescence display device 1 according to the first variation. FIG. 6 is a cross-sectional view taken along the line VI-VI in FIG. 5.

The above embodiment has been described with reference to the case where the first organic sealing layer 52 contained in the barrier structure 50 is divided for each of the pixel areas 6 in a plan view, but not necessarily, and the first organic sealing layer maybe divided for each set of a plurality of the pixel areas 6. In other words, the display area 3 includes a plurality of sub areas including a plurality of the pixel areas 6, and the first organic sealing layer 52 is divided for each of the plurality of the sub areas in the plain view.

In a barrier structure 1050 according to the present variation, a first organic sealing layer 1052 is divided by a first inorganic sealing layer 1051 and a second inorganic sealing layer 1053 for each set of a plurality of the pixel areas 6, as shown in FIGS. 5 and 6. In the example shown in FIG. 5, the first organic sealing layer 1052 is divided for each set of three pixel areas 6. More specifically, the first organic sealing layer 1052 is divided for each set of three pixel areas 6 including one red pixel area 6R, one green pixel area 6G, and one blue pixel area 6B. A division line 1007 is an area where the first organic sealing layer 1052 is divided (more specifically, longitudinal division line 1007b linearly extending along frontward/rearward direction (Y-axis direction)). The division line 1007 is disposed in the third inter-pixel area 6 counted from the inter-pixel area 6 where the preceding division line 1007 is disposed.

Although not shown, white pixel areas that output white light may be formed as part of the pixel areas 6. In this case, the first organic sealing layer 1052 may be divided for each set of four pixel areas 6 including one red pixel area 6R, one green pixel area 6G, one blue pixel area 6B, and one white pixel area. In a case where one primary pixel is formed of a red pixel area 6R, a green pixel area 6G, and a blue pixel area 6B (as well as white pixel area), the division lines 1007 may be so formed as to surround the primary pixels. That is, the division lines 1007 may be formed for each set of a plurality of the primary pixels formed in the display area 3.

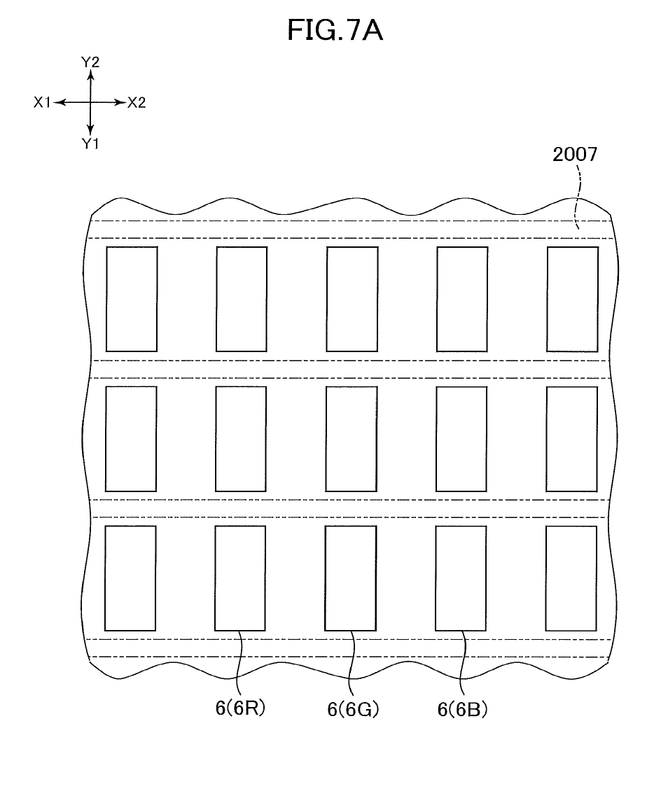

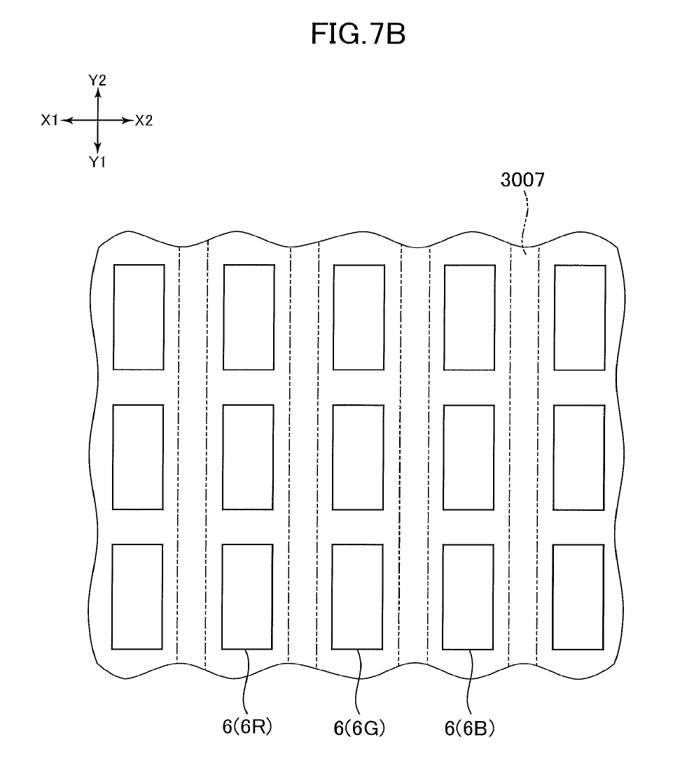

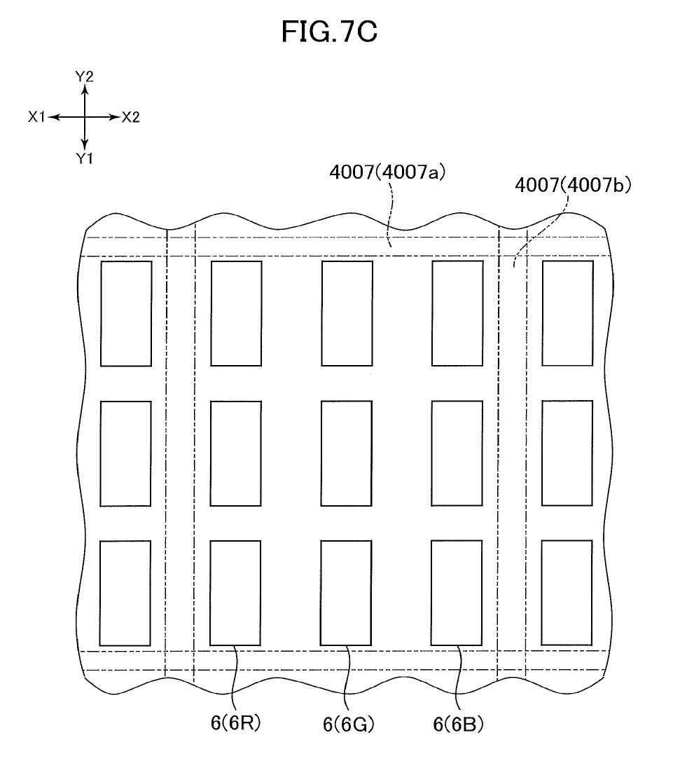

FIGS. 7A to 7C show other variations of the organic electroluminescence display device 1 according to the first variation and each show an upper surface that is an enlarged portion of the display area 3. In the example shown in FIG. 7A, division lines 2007, which are areas where the first organic sealing layer 1052 is divided, extend along the rightward/leftward direction (X-axis direction). In this case, the division lines 2007 do not necessarily extend in the rightward/leftward direction (X-axis direction), and division lines 2007 that cross the entire first organic sealing layer may divide the first organic sealing layer into a plurality of areas. The division lines 2007 may not necessarily be located between all pixel areas 6 adjacent in the upward/downward direction and may be disposed for each set of a plurality of the pixel areas 6 in the upward/downward direction.

In the example shown in FIG. 7B, division lines 3007 extend along the frontward/rearward direction (Y-axis direction). The division lines 3007 do not necessarily extend in the frontward/rearward direction (Y-axis direction). Further, in the example shown in FIG. 7B, a plurality of red pixel areas 6R are arranged along the frontward/rearward direction, and the green pixel areas 6G and the blue pixel areas 6B are similarly arranged in the frontward/rearward direction. Therefore, the division lines 3007 disposed between the pixel areas 6 adjacent in the rightward/leftward direction divide the first organic sealing layer for each of the colors of the pixel area 6.

As shown in FIG. 7C, the lateral division lines 4007a, which extend along the rightward/leftward direction, and the longitudinal division lines 4007b, which extend in the frontward/rearward direction, may be disposed for each set of a plurality of the pixel areas 6. For example, in a case where the lateral division lines 4007a are disposed for each set of M (three in the example shown in FIG. 7C) pixel areas 6 and the longitudinal division lines 4007b are disposed for each set of N (three in the example shown in FIG. 7C) pixel areas 6, the first organic sealing layer is divided for each set of M×N (nine in the example shown in FIG. 7C) pixel areas 6.

Also in the variations described above, in which the first organic sealing layer is divided for each set of a plurality of the pixel areas 6, travel of moisture can be blocked at the locations where the first organic sealing layer is divided, whereby a situation in which the moisture widely spreads via the first organic sealing layer can be avoided. In the case where the first organic sealing layer is divided for each set of a plurality of the pixel areas 6, and the formation of the divided portions is performed, for example, by using a laser beam, the period of the formation can be shortened.

### [2-2. Second Variation]

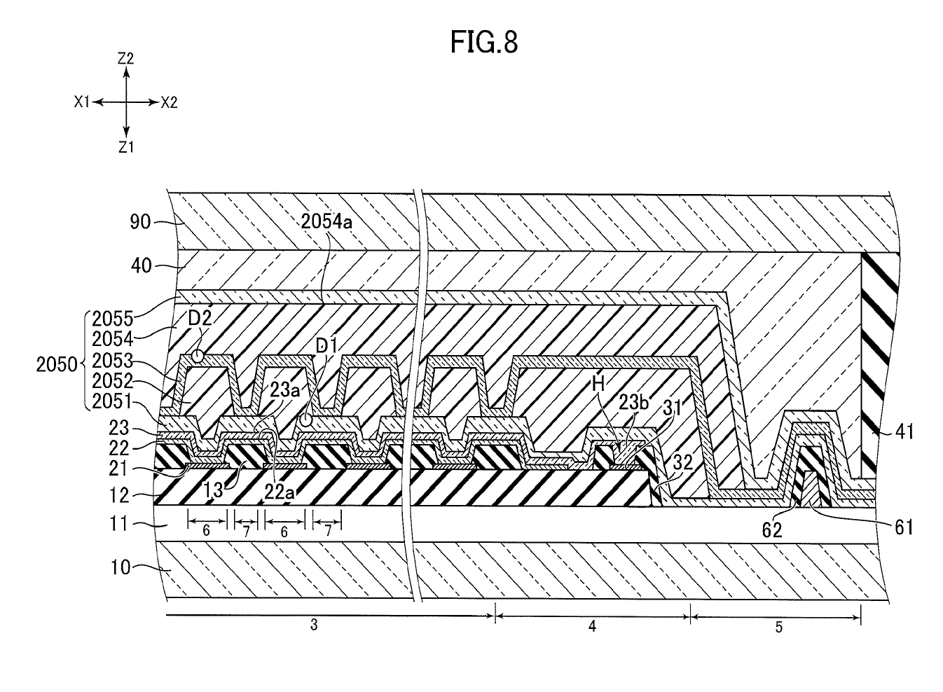

A second variation will be described below with reference to FIG. 8. FIG. 8 is a cross-sectional view of an organic electroluminescence display device 1 according to the second variation and corresponds to the cross-sectional view of FIG. 3 shown in the embodiment.

In a barrier structure 2050 according to the present variation, a first inorganic sealing layer 2051, a first organic sealing layer 2052, and a second inorganic sealing layer 2053, which are the same as those in the embodiment, are layered on each other, and a second organic sealing layer 2054, which is formed on the upper side of the second inorganic sealing layer 2053, and a third inorganic sealing layer 2055, which is formed on the upper side of the second organic sealing layer 2054, are formed as shown in FIG. 8. The third inorganic sealing layer 2055 is so disposed as to cover the second inorganic sealing layer 2053, and the second organic sealing layer 2054 is disposed between the second inorganic sealing layer 2053 and the third inorganic sealing layer 2055.

The second organic sealing layer 2054 is made of an organic insulating material, such as a resin. The second organic sealing layer 2054 is continuously placed on the second inorganic sealing layer 2053 and covers the second inorganic sealing layer 2053 in the display area 3 and the circumferential edge area 4. In the present variation, the second organic sealing layer 2054 is so formed that the second organic sealing layer 2054 fills the portions where the first organic sealing layer 2052 is divided and covers the second inorganic sealing layer 2053 and that an upper surface 2054a extending over the display area 3 and the circumferential edge area 4 is planarized. Further, the second organic sealing layer 2054 extends beyond the end of the first organic sealing layer 2052 to a point close to the first and second insulating layers 61, 62.

The third inorganic sealing layer 2055 is made of an inorganic insulating material, such as SiOx or SiNy. The third inorganic sealing layer 2055 is continuously placed on the second inorganic sealing layer 2053 and covers the second inorganic sealing layer 2053 in the display area 3 and the circumferential edge area 4. Further, the third inorganic sealing layer 2055 is in contact with the second inorganic sealing layer 2053 in the portion which is outside the circumferential edge area 4 and where no second organic sealing layer 2054 is formed. In the moisture blocking area 5, the second organic sealing layer 2054 is isolated from the filler layer that is not shown by the second inorganic sealing layer 2053 and the third inorganic sealing layer 2055. Isolating the second organic sealing layer 2054 made of an organic material can prevent moisture from externally passing through the organic layer and intruding into the light emitting organic layer 22 or the variety of electrodes.

In addition to the three layers formed of the first inorganic sealing layer 2051, the first organic sealing layer 2052, and the second inorganic sealing layer 2053, further layering the two layers formed of the second organic sealing layer 2054 and the third inorganic sealing layer 2055 as described above allows further improvement in the performance of sealing the light emitting organic layer 22. That is, the second organic sealing layer 2054 can cover the foreign matter D2, which adheres to the second inorganic sealing layer 2053, and the third inorganic sealing layer 2055 can prevent moisture from intruding into a hole or any other defect formed in the second organic sealing layer 2054 or the second inorganic sealing layer 2053. The second organic sealing layer 2054, which is continuously formed in the display area 3 as described above, absorbs bending stress produced in a case where the organic electroluminescence display device 1 is a flexible display and when the organic electroluminescence display device 1 is bent, whereby a situation in which an inner film in the organic electroluminescence display device 1 breaks or peels off can be avoided.

### [2-3. Third Variation]

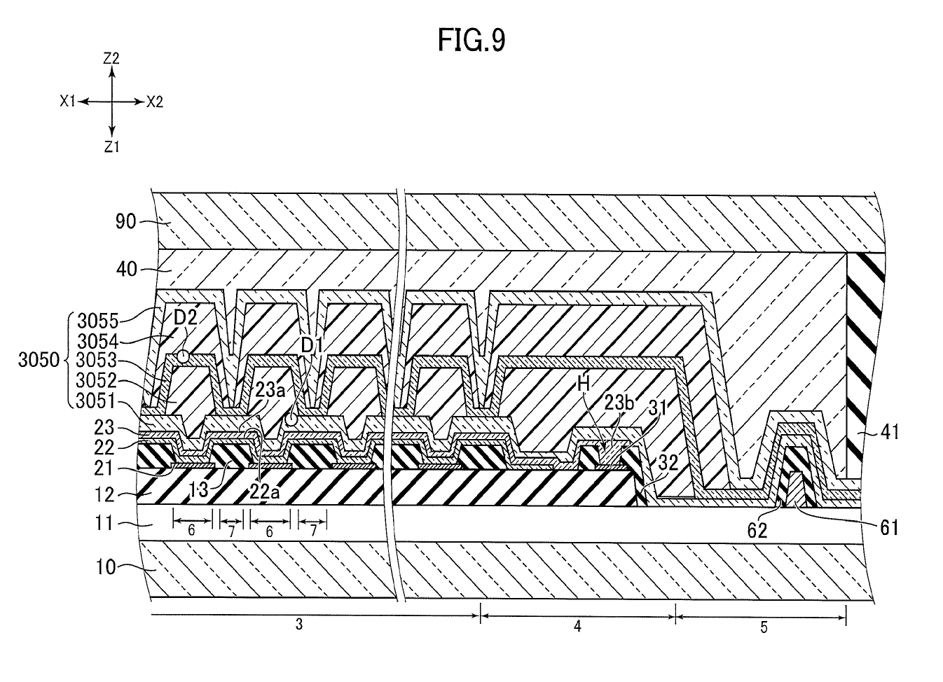

A third variation will be described below with reference to FIG. 9. FIG. 9 is a cross-sectional view of an organic electroluminescence display device 1 according to the third variation and corresponds to the cross-sectional view of FIG. 3 shown in the embodiment.

A barrier structure 3050 according to the present variation includes a first inorganic sealing layer 3051, a first organic sealing layer 3052, a second inorganic sealing layer 3053, a second organic sealing layer 3054, and a third inorganic sealing layer 3055, as in the second variation, as shown in FIG. 9. The second organic sealing layer 3054 according to the present variation differs from the second organic sealing layer 2054 in the second variation in that the second organic sealing layer 3054 is divided by the third inorganic sealing layer 3055 at each predetermined area.

More specifically, the second organic sealing layer 3054 is divided at the positions where the bank 13 is disposed (that is, along boundaries between two adjacent pixel areas 6), as the first organic sealing layer 3052 is. Further, at the locations where the second organic sealing layer 3054 is divided, the third inorganic sealing layer 3055 is in contact with the second inorganic sealing layer 3053. Dividing the second organic sealing layer 3054 into a plurality of areas as described above can prevent moisture from widely spreading via the second organic sealing layer 3054.

In the example shown in FIG. 9, the second organic sealing layer 3054 is divided at all locations where the first organic sealing layer 3052 is divided, but the second organic sealing layer 3054 may not necessarily be divided at the locations where the first organic sealing layer 3052 is divided. For example, in the case where the first organic sealing layer 3052 is divided for each set of three pixel areas 6, as in the first variation, the second organic sealing layer 3054 may be divided for each set of six pixel areas 6, which is a multiple of three or may be divided for each set of nine pixel areas 6, which is also a multiple of three.

### [2-4. Fourth Variation]

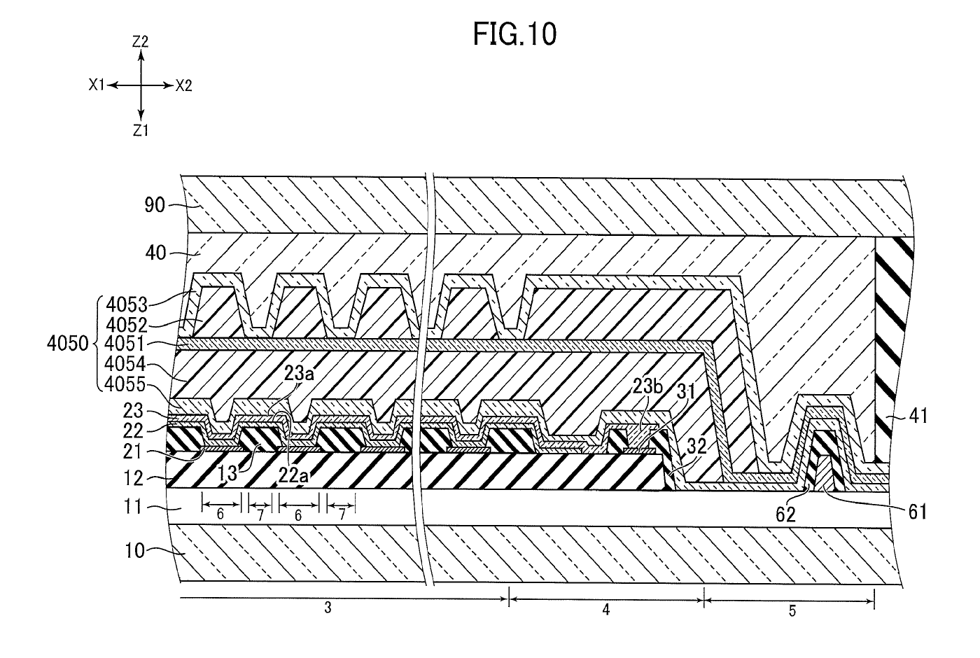

A fourth variation will be described below with reference to FIG. 10. FIG. 10 is a cross-sectional view of an organic electroluminescence display device 1 according to the fourth variation and corresponds to the cross-sectional view of FIG. 3 shown in the embodiment.

In a barrier structure 4050 according to the present variation, below a first inorganic sealing layer 4051, a first organic sealing layer 4052, and a second inorganic sealing layer 4053 (on Z1-direction side), a second organic sealing layer 4054 and a third inorganic sealing layer 4055 are formed, as shown in FIG. 10. More specifically, the barrier structure 4050 includes the third inorganic sealing layer 4055, which is so disposed to cover the first inorganic sealing layer 4051, and the second organic sealing layer 4054, which is disposed between the first inorganic sealing layer 4051 and the third inorganic sealing layer 4055.

In the present variation, the layers described above are so formed that the third inorganic sealing layer 4055 is placed on the upper electrode 23, and that the second organic sealing layer 4054, the first inorganic sealing layer 4051, the first organic sealing layer 4052, and the second inorganic sealing layer 4053 are sequentially placed on the third inorganic sealing layer 4055. The first to third inorganic sealing layer 4051, 4053, 4055 continuously extend over the display area 3, the circumferential edge area 4, and the moisture blocking area 5.

Further, in the present variation, the second organic sealing layer 4054 is not divided in the display area 3, and the first organic sealing layer 4052, which is formed above the second organic sealing layer 4054, is divided by the first inorganic sealing layer 4051 and the second inorganic sealing layer 4053 in the positions where the bank 13 is disposed. Dividing the first organic sealing layer 4052 into a plurality of areas as described above prevents moisture having intruded into the first organic sealing layer 4052 from reaching the portion below the first inorganic sealing layer 4051. In other words, as long as the first organic sealing layer 4052 is divided into a plurality of areas, even in the case where the second organic sealing layer 4054 located below the first organic sealing layer 4052 is not divided into a plurality of areas, a situation in which moisture intrudes into the upper electrode 23 and the light emitting organic layer 22 can be avoided. Further, the second organic sealing layer 4054, which is continuously formed in the display area 3, absorbs bending stress produced in the case where the organic electroluminescence display device 1 is a flexible display and when the organic electroluminescence display device 1 is bent, whereby a situation in which an inner film in the organic electro luminescence display device 1 breaks or peels off can be avoided.

### [2-5. Fifth Variation]

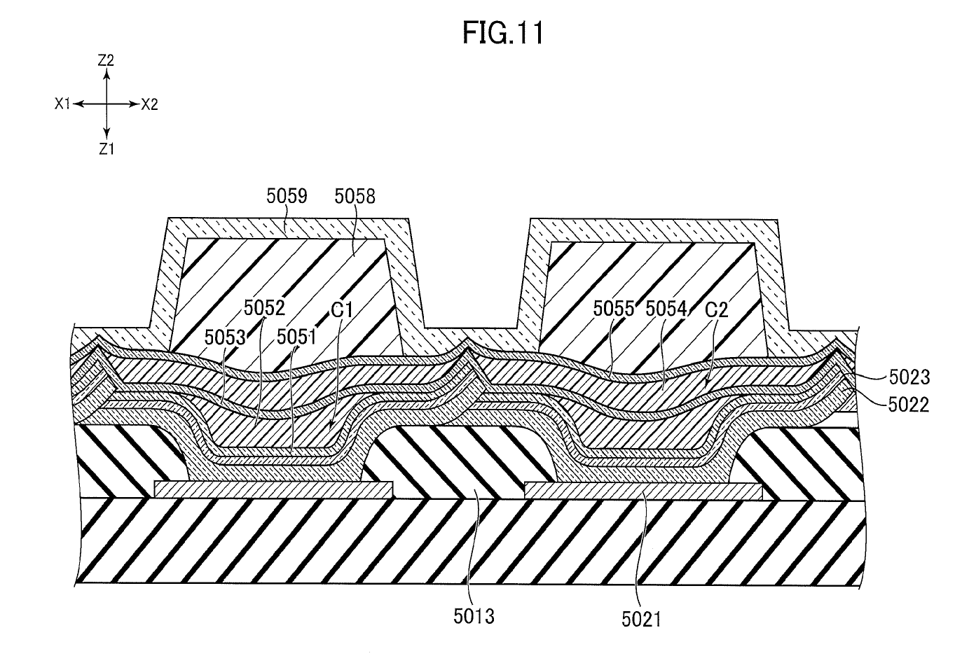

A fifth variation will be described below with reference to FIG. 11. FIG. 11 is a cross-sectional view of an organic electroluminescence display device 1 according to the fifth variation.

In the present variation, a light emitting organic layer 5022, which is formed on lower electrodes 5021 and a bank 5013, is climbing an end portion of the adjacent light emitting organic layer 5022, and the step produced by the climbing light emitting organic layer divides an upper electrode 5023, which is disposed on the upper side of the light emitting organic layers 5022, into a plurality of areas. Further, as a barrier structure 5050, a first inorganic sealing layer 5051 and a first organic sealing layer 5052 are so layered on each other as to fill recesses C1 formed above the upper electrode 5023 formed in correspondence with the shape of the bank 5013, and a second inorganic sealing layer 5053 is so formed as to cover the first organic sealing layer 5052. Further, a second organic sealing layer 5054 is so formed as to fill recesses C2 formed by the light emitting organic layers 5022, each of which is climbing the end portion of the adjacent light emitting organic layer 5022, and the second inorganic sealing layer 5053, which is placed on the climbing portions, and a third inorganic sealing layer 5055 covers the second organic sealing layer 5054.

In a case where the first to third inorganic sealing layers 5051, 5053, and 5055 are very thin, the inorganic sealing layers described above are also undesirably divided by the steps produced by the light emitting organic layer 5022 and the upper electrode 5023, and sufficient sealing performance is not possibly provided.

To avoid the problem described above, a third organic sealing layer 5058, which is thicker than the bank 5013, and a fourth inorganic sealing layer 5059, which is thicker than the light emitting organic layer 5022, are placed on the third inorganic sealing layer 5055, and the third organic sealing layer 5058 is divided by the fourth inorganic sealing layer 5059 in the positions where the bank 5013 is formed for further improvement in the performance of sealing the light emitting organic layer 5022. That is, increasing the thickness of the fourth inorganic sealing layer 5059 can prevent the fourth inorganic sealing layer 5059 from being divided by the steps produced by the light emitting organic layer 5022 and the upper electrode 5023. Further, increasing the thickness of the third organic sealing layer 5058 allows foreign matter having a size greater than the thickness of the bank 5013 to be covered. Moreover, dividing the third organic sealing layer 5058 into a plurality of areas can prevent moisture from widely spreading in the third organic sealing layer 5058, whereby a situation in which the moisture intrudes into the upper electrode 5023 and the light emitting organic layer 5022 can be avoided.

While there have been described what are at present considered to be certain embodiments of the invention, it will be understood that various modifications may be made thereto, and it is intended that the appended claim cover all such modifications as fall within the true spirit and scope of the invention.

What is claimed is:

1. An organic electroluminescence display device comprising:
a display area where a plurality of pixels are arranged;
a plurality of lower electrodes each arranged in each of the plurality of pixels;
a bank that is provided between adjacent two of the pixels, covers a periphery of each of the lower electrodes, and has a shape that rises upward;
a light emitting organic layer that is continuously placed on the plurality of lower electrodes and the bank, the light emitting organic layer having first raised sections that rise in corresponding with the shape of the bank;
an upper electrode that is continuously placed on the light emitting organic layer and is placed above the plurality of lower electrodes and the bank, the upper electrode having second raised sections that rise in correspondence with the first raised sections of the light emitting organic layer; and
a barrier structure that is placed on the upper electrode,
wherein the barrier structure has
a first inorganic sealing layer,
a second inorganic sealing layer covering the first inorganic sealing layer, and
a first organic sealing layer disposed between the first inorganic sealing layer and the second inorganic sealing layer and divided by the second inorganic sealing layer with respect to each of a plurality of partial areas that form the display area in a plan view, and
the first organic sealing layer is thicker than the bank.

2. The organic electroluminescence display device according to claim 1,
wherein the first organic sealing layer is divided at a position where the bank is disposed in the plan view.

3. The organic electroluminescence display device according to claim 2,
wherein the display area including a plurality of sub areas including a plurality of the pixels,
the first organic sealing layer is divided for each of the plurality of the sub areas in the plan view.

4. The organic electroluminescence display device according to claim 1,
wherein the barrier structure further has
a third inorganic sealing layer covering the second inorganic sealing layer, and
a second organic sealing layer disposed between the second inorganic sealing layer and the third inorganic sealing layer.

5. The organic electroluminescence display device according to claim 4,
wherein the second organic sealing layer is divided by the third inorganic sealing layer with respect to each of the plurality of partial areas that form the display area in the plan view.

6. The organic electroluminescence display device according to claim 5,
wherein the second organic sealing layer is divided at a position where the bank is disposed in the plan view.

7. The organic electroluminescence display device according to claim 1,
wherein the barrier structure further has
a third inorganic sealing layer covering the first inorganic sealing layer, and
a second organic sealing layer disposed between the first inorganic sealing layer and the third inorganic sealing layer.

8. The organic electroluminescence display device according to claim 1,
wherein the first organic sealing layer is isolated by the first inorganic sealing layer and the second inorganic sealing layer in an area outside the display area.

9. An organic electroluminescence display device comprising:
a display area where a plurality of pixels are arranged;
a plurality of lower electrodes each arranged in each of the plurality of pixels;
a bank that is provided between adjacent two of the pixels, covers a periphery of each of the lower electrodes, and has a shape that rises upward;
a light emitting organic layer that is continuously placed on the plurality of lower electrodes and the bank , the light emitting organic layer having first raised sections that rise in corresponding with the shape of the bank;
an upper electrode that is continuously placed on the light emitting organic layer and is placed above the plurality of lower electrodes and the bank, the upper electrode having second raised sections that rise in correspondence with the first raised sections of the light emitting organic layer; and
a barrier structure that is placed on the upper electrode,
wherein the barrier structure has
a first inorganic sealing layer,
a second inorganic sealing layer covering the first inorganic sealing layer, and
a first organic sealing layer disposed between the first inorganic sealing layer and the second inorganic sealing layer and divided by the second inorganic sealing layer with respect to each of a plurality of partial areas that form the display area in a plan view, and
the first inorganic sealing layer is thicker than the lower electrodes, the light emitting organic layer, and the upper electrode.
